(19) United States
(12) Patent Application Publication
(10) Pub. No.: US 2019/0108896 A1
(43) Pub. Date: Apr. 11, 2019

(54) SYSTEMS AND METHODS FOR PROVIDING POST-PACKAGE REPAIR VISIBILITY TO A HOST FOR MEMORY RELIABILITY, AVAILABILITY, AND SERVICEABILITY

(71) Applicant: Dell Products L.P., Round Rock, TX (US)

(72) Inventors: Stuart Allen BERKE, Austin, TX (US); Vadhiraj SANKARANARAYANAN, Austin, TX (US); Bhyrav M. MUTNURY, Round Rock, TX (US)

(73) Assignee: Dell Products L.P., Round Rock, TX (US)

(21) Appl. No.: 15/726,065

(22) Filed: Oct. 5, 2017

(51) Int. Cl. G11C 29/00

(52) U.S. Cl. CPC G11C 29/76; G11C 2029/4402; G11C 29/802; G11C 29/789

(57) ABSTRACT

An information handling system comprising a processor, a memory system communicatively coupled to the processor, the memory system comprising a plurality of spare rows for post-package repair of the memory system, and one or more instructions stored in non-transitory computer readable media and configured to, when executed, cause the processor to: communicate a command to the memory system requesting information associated with an availability of spare rows for post-package repair of the memory system and receive a response to the command, the command comprising the information associated with the availability.

### TECHNICAL FIELD

The present disclosure relates in general to information handling systems, and more particularly to systems and methods for providing post-package repair visibility to a host for memory reliability, availability, and serviceability.

### BACKGROUND

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Information handling systems often use memories to store data. A type of memory often used is dynamic random access memory (DRAM). Demand for higher memory capacities on high-performance servers has propelled a corresponding consistent increase on the densities of DRAMs and, hence, on the memory modules themselves from one server generation to the next. DRAM densities of 8 Gb have become commonplace in existing dual-inline memory modules (DIMMs), and as per projections by DIMM vendors, DRAM densities of 16 Gb and even 32 Gb may be used in coming years. In spite of the increase in the DRAM densities on modern DIMM modules, DIMM vendors' technical projections highlight an increasing likelihood of failure rates as the DRAM geometries continue to shrink to smaller process technologies. In that vein, DRAM row-based failures are becoming increasingly common with these smaller geometry based DRAMs. Hence, an increase in both the number of DRAMs on a module and DRAM densities in these smaller process technologies calls for higher memory reliability, availability, and serviceability (RAS) capabilities than presently available.

Post-Package Repair (PPR) is one such new feature that was introduced in recent years in the DDR4 specification to address the row-based failures. This feature, as per the current Joint Electron Device Engineering Council (JEDEC) memory standard, allows for one spare row per DDR4 bank-group that can be used to replace a faulty row either permanently by blowing a fuse (hard PPR) or temporarily only for a particular boot session (soft PPR). It is highly possible that future DRAM standards on PPR will include support for additional spare rows, instead of a single spare per bank group.

Although the PPR feature comes as a reprieve for the requirement of DRAM-level RAS features, it does suffer from one severe limitation as it stands today—there is zero visibility to the host processor regarding the availability of a number of available spares on a given DRAM. As per the PPR functionality in existing information handling systems, a host simply assumes that there is a spare available and performs a PPR operation blindly. It can be a hit or miss and the host comes to know the success of a PPR operation based on the write and read transactions only after the PPR operation.

### SUMMARY

In accordance with the teachings of the present disclosure, the disadvantages and problems associated with utilizing post-package repair capability in an information handling system may be reduced or eliminated.

In accordance with embodiments of the present disclosure, an information handling system comprising a processor, a memory system communicatively coupled to the processor, the memory system comprising a plurality of spare rows for post-package repair of the memory system, and one or more instructions stored in non-transitory computer readable media and configured to, when executed, cause the processor to: communicate a command to the memory system requesting information associated with an availability of spare rows for post-package repair of the memory system and receive a response to the command, the command comprising the information associated with the availability.

In accordance with these and other embodiments of the present disclosure, a method may include communicating a command from to a memory system comprising a plurality of spare rows for post-package repair of the memory system, the command for requesting information associated with an availability of spare rows for post-package repair of the memory system. The method may further include receiving a response to the command, the command comprising the information associated with the availability.

In accordance with these and other embodiments of the present disclosure, an article of manufacture may include a non-transitory computer-readable medium and computer-executable instructions carried on the computer-readable medium, the instructions readable by a processor, the instructions, when read and executed, for causing the processor to: communicate a command from to a memory system comprising a plurality of spare rows for post-package repair of the memory system, the command for requesting information associated with an availability of spare rows for post-package repair of the memory system and receive a response to the command, the command comprising the information associated with the availability.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 illustrates a block diagram of an example information handling system in accordance with embodiments of the present disclosure;

FIG. 2 illustrates a block diagram of an example memory chip in accordance with embodiments of the present disclosure;

FIG. 3 illustrates a flow chart of an example method for providing post-package repair visibility for a memory to a host, in accordance with embodiments of the present disclosure; and

FIG. 4 illustrates a flow chart of another example method for providing post-package repair visibility for a memory to a host, in accordance with embodiments of the present disclosure.

### DETAILED DESCRIPTION

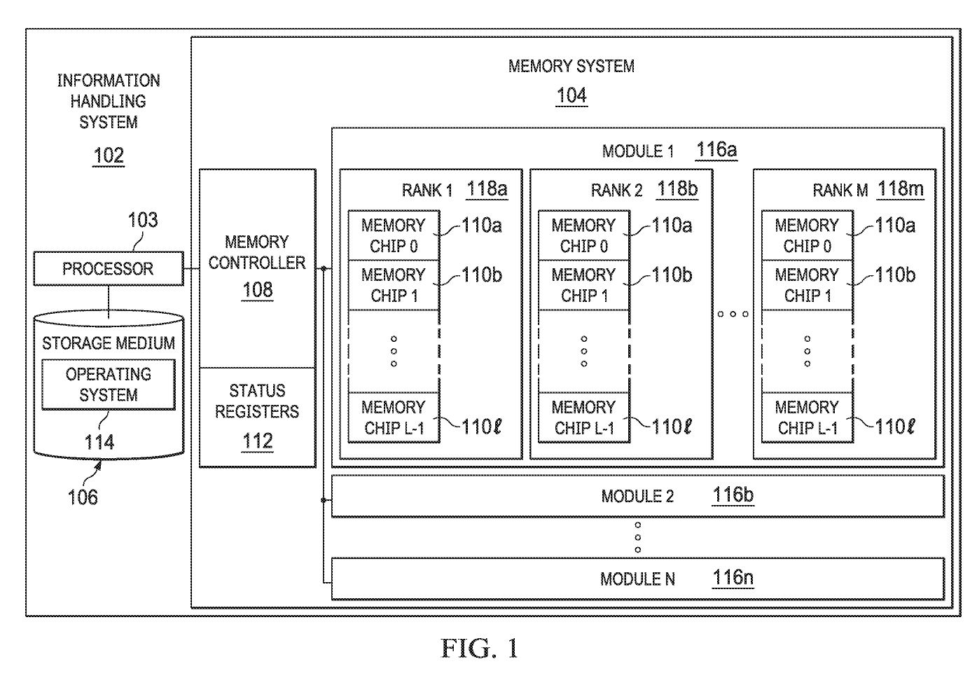

Preferred embodiments and their advantages are best understood by reference to FIGS. 1 through 4, wherein like numbers are used to indicate like and corresponding parts. For the purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an information handling system may be a personal computer, a personal digital assistant (PDA), a consumer electronic device, a network storage device, or any other suitable device and may vary in size, shape, performance, functionality, and price. The information handling system may include memory, one or more processing resources such as a central processing unit (“CPU”) or hardware or software control logic. Additional components of the information handling system may include one or more storage devices, one or more communications ports for communicating with external devices as well as various input/output (“I/O”) devices, such as a keyboard, a mouse, and a video display. The information handling system may also include one or more buses operable to transmit communication between the various hardware components.

For the purposes of this disclosure, computer-readable media may include any instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory; as well as communications media such as wires, optical fibers, microwaves, radio waves, and other electromagnetic and/or optical carriers; and/or any combination of the foregoing.

For the purposes of this disclosure, information handling resources may broadly refer to any component system, device or apparatus of an information handling system, including without limitation processors, service processors, basic input/output systems, buses, memories, I/O devices and/or interfaces, storage resources, network interfaces, motherboards, and/or any other components and/or elements of an information handling system.

FIG. 1 illustrates a block diagram of an example information handling system 102 in accordance with certain embodiments of the present disclosure. In certain embodiments, information handling system 102 may comprise a computer chassis or enclosure (e.g., a server chassis holding one or more server blades). In other embodiments, information handling system 102 may be a personal computer (e.g., a desktop computer or a portable computer). As depicted in FIG. 1, information handling system 102 may include a processor 103, a memory system 104 communicatively coupled to processor 103, and a storage medium 106 communicatively coupled to processor 103.

Processor 103 may include any system, device, or apparatus configured to interpret and/or execute program instructions and/or process data, and may include, without limitation a microprocessor, microcontroller, digital signal processor (DSP), application specific integrated circuit (ASIC), or any other digital or analog circuitry configured to interpret and/or execute program instructions and/or process data. In some embodiments, processor 103 may interpret and/or execute program instructions and/or process data stored and/or communicated by one or more of memory system 104, storage medium 106, and/or another component of information handling system 102.

Memory system 104 may be communicatively coupled to processor 103 and may comprise any system, device, or apparatus operable to retain program instructions or data for a period of time (e.g., computer-readable media). Memory system 104 may comprise random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to information handling system 102 is turned off. In particular embodiments, memory system 104 may comprise dynamic random access memory (DRAM).

As shown in FIG. 1, memory system 104 may include memory controller 108, one or more memory modules 116a-116n communicatively coupled to memory controller 108, and status registers 112 communicatively coupled to memory controller 108. Memory controller 108 may be any system, device, or apparatus configured to manage and/or control memory system 104. For example, memory controller 108 may be configured to read data from and/or write data to memory modules 116 comprising memory system 104. Additionally or alternatively, memory controller 108 may be configured to refresh memory modules 116 and/or memory chips 110 thereof in embodiments in which memory system 104 comprises DRAM. Although memory controller 108 is shown in FIG. 1 as an integral component of memory system 104, memory controller 108 may be separate from memory system 104 and/or may be an integral portion of another component of information handling system 102 (e.g., memory controller 108 may be integrated into processor 103).

Each memory module 116 may include any system, device or apparatus configured to retain program instructions and/or data for a period of time (e.g., computer-readable media). A memory module 116 may comprise a dual in-line package (DIP) memory, a dual-inline memory module (DIMM), a Single In-line Pin Package (SIPP) memory, a Single Inline Memory Module (SIMM), a Ball Grid Array (BGA), or any other suitable memory module.

As depicted in FIG. 1, each memory module 116 may include one or more ranks 118a-118m. Each memory rank 118 within a memory module 116 may be a block or area of data created using some or all of the memory capacity of the memory module 116. In some embodiments, each rank 118 may be a rank as such term is defined by the JEDEC Standard for memory devices.

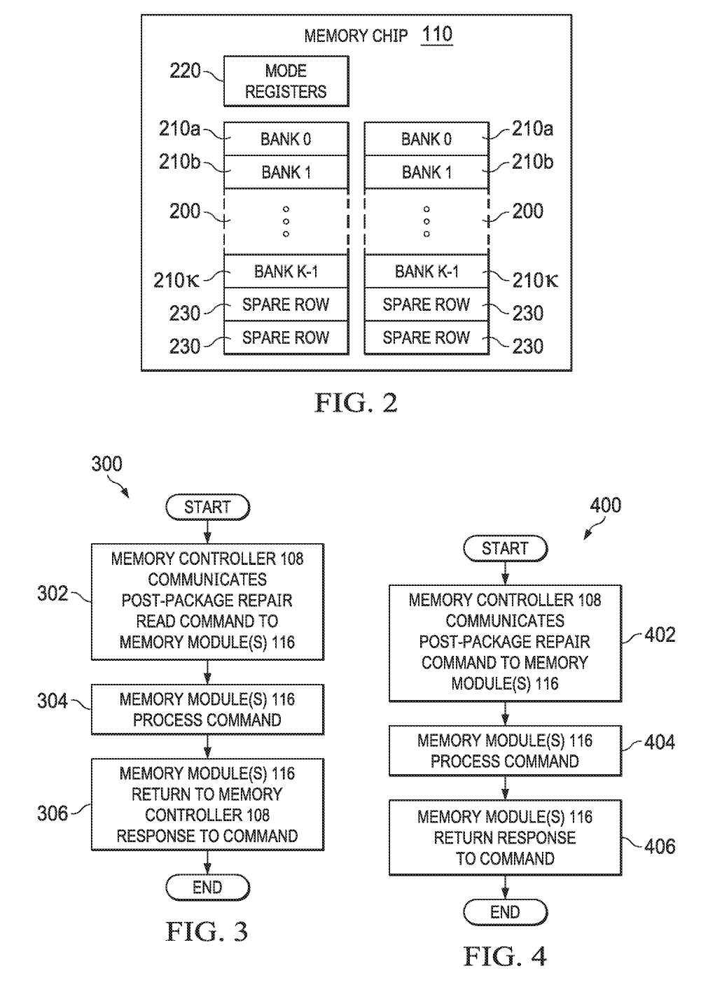

As shown in FIG. 1, each rank 118 may include a plurality of memory chips 110. Each memory chip 110 may include a packaged integrated circuit configured to comprise a plurality of memory cells for storing data. In some embodiments, a memory chip 110 may include dynamic random access memory (DRAM). Selected components of a memory chip 110 are illustrated in greater detail in FIG. 2 below.

Status registers 112 may include one or more configuration variables and/or parameters associated with memory system 104. When reading, writing, refreshing, and/or performing other operations associated with memory system 104, memory controller 108 may carry out such operations based at least in part on configuration parameters and/or variables stored in status registers 112. In some embodiments, status registers 112 may include registers similar to mode registers 220 (FIG. 2).

Storage medium 106 may be communicatively coupled to processor 104. Storage medium 106 may include any system, device, or apparatus operable to store information processed by processor 103. Storage medium 106 may include, for example, network attached storage, one or more direct access storage devices (e.g., hard disk drives), and/or one or more sequential access storage devices (e.g., tape drives). As shown in FIG. 1, storage medium 106 may have stored thereon an operating system (OS) 114. OS 114 may be any program of executable instructions, or aggregation of programs of executable instructions, configured to manage and/or control the allocation and usage of hardware resources such as memory, CPU time, disk space, and input and output devices, and provide an interface between such hardware resources and application programs hosted by OS 114. Active portions of OS 114 may be transferred to memory 104 for execution by processor 103.

In addition to processor 103, memory 104, and storage medium 106, information handling system 102 may include one or more other information handling resources.

FIG. 2 illustrates a block diagram of an example memory chip 110 in accordance with embodiments of the present disclosure. A memory chip 110 may include mode registers 220 and a plurality of bank groups 200. Each memory bank 210 may be a logical unit of storage within memory chip 110.

Mode registers 220 may include one or more configuration variables and/or parameters associated with memory chip 110. When reading, writing, refreshing, and/or performing other operations associated with memory system 104, a memory module 116 may carry out such operations based at least in part on configuration parameters and/or variables stored in mode registers 220. In some embodiments, mode registers 220 may be defined by a JEDEC standard for memory devices.

Each memory bank group 200 may comprise a plurality of memory banks 210 and one or more spare rows 230. Each memory bank 210 may be a logical unit of storage within memory chip 110, and may include a plurality of memory rows, wherein each row comprises a plurality of memory cells. A spare row 230 may comprise an extra row of memory that may be used in place of a non-functioning row of a memory bank 210. In some embodiments, topology, functionality, and/or use of spare rows 230 may be defined by a JEDEC standard for memory devices.

For clarity and exposition, FIG. 2 depicts memory chip 110 having two memory bank groups 200. However, memory chip 110 may include any suitable number of bank groups 200.

Also for clarity and exposition, FIG. 2 depicts each memory bank group 200 comprising two spare rows 230. However, a memory bank group 200 may include any suitable number of spare rows 230. For example, the JEDEC DDR4 standard calls for four banks per bank group and four bank groups per die for 16 banks total per die. The JEDEC DDR5 standard calls for four banks per bank group and eight bank groups per die for 32 total banks per die. Both the DDR4 and DDR5 standards call for one spare row per bank group. In operation, a host system (e.g., operating system 114 executing on processor 103) may be configured to query a memory system to obtain host-visibility into the availability of spare rows 230, as described in greater detail below.

FIG. 3 illustrates a flow chart of an example method 300 for providing post-package repair visibility for a memory to a host, in accordance with embodiments of the present disclosure. According to some embodiments, method 300 may begin at step 302. As noted above, teachings of the present disclosure may be implemented in a variety of configurations of information handling system 102. As such, the preferred initialization point for method 300 and the order of the steps comprising method 300 may depend on the implementation chosen.

At step 302, memory controller 108 may communicate a post-package repair read command to one or more memory modules 116 of memory system 104. Such command may be implemented using an associated opcode of a memory standard (e.g., a DDR standard) or may be implemented using a vendor-specific opcode not otherwise used in a memory standard. The post-package repair read command may include one or more arguments, including one or more arguments identifying a particular memory location. Such one or more arguments may identify a memory module 116, a memory rank 118, a memory chip 110, a memory bank group 200, a memory bank 210, and/or a memory row.

At step 304, a memory module 116 may receive such post-package repair read command, and process the command to determine an appropriate response. For example, memory controller 108 may query a particular memory location to determine a number and/or a location of spare rows 230. In some embodiments, such particular memory location may comprise a bank 210 or a bank group 200, such that the bank or bank group responds with the number and/or location of spare rows 230 associated with such bank 210 or bank group 200.

At step 306, the memory controller 116 may return to the memory controller 108 a response to the command. Such response may include with it any appropriate data responsive to the command, including a number of spare rows 230 and/or memory locations of such spare rows. In some embodiments, the response may

In some embodiments, each spare row 230 may be restricted for use with a particular bank 210 or bank group 200. In such embodiments, memory controller 108 operating in accordance with method 300 may query a bank group 200 to see if a memory address that falls in such bank group 200 requires a replacement spare. Thus, memory controller 108 may send a request for determining a number of spare rows 230 for such bank group 200. If the number of spare rows 230 is one or more, then the host system may communicate a post-package repair command (e.g., as in method 400 described below) to request replacement of an address within such bank group 200 with a spare row 230.

Although FIG. 3 discloses a particular number of steps to be taken with respect to method 300, method 300 may be executed with greater or fewer steps than those depicted in FIG. 3. In addition, although FIG. 3 discloses a certain order of steps to be taken with respect to method 300, the steps comprising method 300 may be completed in any suitable order.

Method 300 may be implemented using processor 103, memory controller 108, and/or any other system operable to implement method 300. In certain embodiments, method 300 may be implemented partially or fully in software and/or firmware embodied in computer-readable media.

FIG. 4 illustrates a flow chart of another example method 300 for providing post-package repair visibility for a memory to a host, in accordance with embodiments of the present disclosure. According to some embodiments, method 400 may begin at step 402. As noted above, teachings of the present disclosure may be implemented in a variety of configurations of information handling system 102. As such, the preferred initialization point for method 400 and the order of the steps comprising method 400 may depend on the implementation chosen.

At step 402, memory controller 108 may send a post-package repair command in accordance with JEDEC or other relevant standard to one or more memory modules, to request replacement of an address within a particular memory location (e.g., within a particular bank group 200 or bank 210) with a spare row 230. In response to receipt of the post-package repair command, at step 404 a memory module 116 may process the command and replace a particular memory location with an available spare row. At step 406, the memory module 116 may return to memory controller 108 a response to the command, indicating that the particular memory address has been replaced with a spare row.

Although FIG. 4 discloses a particular number of steps to be taken with respect to method 400, method 400 may be executed with greater or fewer steps than those depicted in FIG. 4. In addition, although FIG. 4 discloses a certain order of steps to be taken with respect to method 400, the steps comprising method 400 may be completed in any suitable order.

Method 400 may be implemented using processor 103, memory controller 108, and/or any other system operable to implement method 400. In certain embodiments, method 400 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

1. An information handling system comprising:
a processor; and
a memory system communicatively coupled to the processor, the memory system comprising a plurality of spare rows for post-package repair of the memory system; and
one or more instructions stored in non-transitory computer readable media and configured to, when executed, cause the processor to:
communicate a command to the memory system requesting information associated with an availability of spare rows for post-package repair of the memory system; and
receive a response to the command, the command comprising the information associated with the availability, wherein the information associated with the availability comprises contents of one or more memory registers of the memory system.

2. The information handling system of claim 1, wherein the information comprises at least one of a number of available spare rows and a memory location of one or more available spare rows.

3. The information handling system of claim 1, wherein the command is implemented using an opcode compatible with a memory standard for the memory system.

4. The information handling system of claim 3, wherein the opcode is defined by the memory standard.

5. The information handling system of claim 3, wherein the opcode is a vendor-specific opcode.

6. (canceled)

7. A method comprising:
communicating a command from to a memory system comprising a plurality of spare rows for post-package repair of the memory system, the command for requesting information associated with an availability of spare rows for post-package repair of the memory system; and
receiving a response to the command, the command comprising the information associated with the availability, wherein the information associated with the availability comprises contents of one or more memory registers of the memory system.

8. The method of claim 7, wherein the information comprises at least one of a number of available spare rows and a memory location of one or more available spare rows.

9. The method of claim 7, wherein the command is implemented using an opcode compatible with a memory standard for the memory system.

10. The method of claim 9, wherein the opcode is defined by the memory standard.

11. The method of claim 9, wherein the opcode is a vendor-specific opcode.

12. (canceled)

13. An article of manufacture comprising:
a non-transitory computer-readable medium; and
computer-executable instructions carried on the non-transitory computer-readable medium, the instructions readable by a processor, the instructions, when read and executed, for causing the processor to:
communicate a command from to a memory system comprising a plurality of spare rows for post-package repair of the memory system, the command for requesting information associated with an availability of spare rows for post-package repair of the memory system; and
receive a response to the command, the command comprising the information associated with the availability, wherein the information associated with the availability comprises contents of one or more memory registers of the memory system.

14. The article of claim 13, wherein the information comprises at least one of a number of available spare rows and a memory location of one or more available spare rows.

15. The article of claim 13, wherein the command is implemented using an opcode compatible with a memory standard for the memory system.

16. The article of claim 15, wherein the opcode is defined by the memory standard.

17. The article of claim 15, wherein the opcode is a vendor-specific opcode.

18. (canceled)
